(19) United States
(12) Patent Application Publication
(10) Pub. No.: US 2008/0159056 A1
(43) Pub. Date: Jul. 3, 2008

(54) INTERNAL ADDRESS GENERATION CIRCUIT AND INTERNAL ADDRESS GENERATION METHOD

(76) Inventors: Ki Chon PARK, Kyoungki-do (KR); Yong Suk JOO, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/779,373

(22) Filed: Jul. 18, 2007

(30) Foreign Application Priority Data
Dec. 27, 2006 (KR) 10-2006-0135719

(51) Int. Cl. G11C 8/00

(52) U.S. Cl. 365/230.08; 365/233.19

(57) ABSTRACT

An internal address generation circuit in a semiconductor memory receives an external address signal and generates an internal address. The internal address generation circuit includes a control unit outputting at least more than two address strobe signals which are different from an internal command signal in terms of a strobe timing by decoding an external command signal; and an internal address generation unit outputting an internal address signal by aligning a first and a second address in a row by using the address strobe signal which are inputted sequentially, and there is an effect that an internal address is generated by using a plurality of address signals which are applied to one pad sequentially.

### CROSS REFERENCE TO RELATED APPLICATIONS

The present application claims priority to Korean patent application number 10-2006-0135719 filed on Dec. 26, 2006, which is incorporated herein by the reference in its entirety.

### BACKGROUND OF THE INVENTION

The present invention relates to a semiconductor memory, and in particular to an internal address generation circuit and a method thereof receiving an external address signal and generating an internal address.

Generally, the semiconductor memory includes a pad corresponding to the number of the address bits applied from outside, buffers an external address signal inputted to each pad and amplifies the buffered signal to a CMOS level, synchronizes it with a clock and latches, and generates an internal address signal. That is, the number of the pads was identical to the number of the bits of the internal address signal. Below, for convenience of explanation, the present invention will be explained with defining the address signal of the present invention as a column address signal.

Referring to FIG. 1 and FIG. 2, an internal address generation circuit and the waveforms of the operations will be explained. Here, tCCD(Cas to Cas Command Delay time) means 2tCK(Clock Period).

The internal address generation circuit includes a command decoder 110, an address buffer 120, an address latch unit 130, 140, and an address generation unit 150.

The command decoder 110 decodes an external command signal (for example, RAS, CAS, WE, CS and etc.) and then outputs an internal command signal COM and an address strobe signal AS. The address buffer 120 buffers an external address signal ADD inputted via a pad and then outputs the buffered signal as an address signal ADD_BUF.

The address latch unit 130 synchronizes the buffered address signal ADD_BUF with a clock signal CLK, latches it for 2tCK, and then outputs it as an address signal ADD_LAT1.

The address latch unit 140 synchronizes and latches the latched address signal ADD_LAT1 with the address strobe signal AS, and then outputs it as an address signal ADD_LAT2.

The address generation unit 150 outputs the address signal ADD_LAT2 which is synchronized and latched with the internal command signal COM as an internal address signal ADD_IN.

However, as the semiconductor memory of a high speed is being developed, JEDEC SPEC of GDDR4(Graph Double Date Rate 4) recommends a Double Pumped Address method in which a plurality of external address signal are applied sequentially to a plurality of clock signal by using a same pad. That is, the Double Pumped Address method is a method in which the number of the pads is reduced to a half, and two address signals are applied sequentially to each pad. Therefore, the internal address generation circuit must generate an internal address signal by separating two address signals which are applied sequentially to each pad. But, as for the conventional internal address generation circuit, there existed a difficult problem in generating an internal address signal by separating two address signals which are applied sequentially from each pad.

The present invention can be used to generate an internal address signal by separating a plurality of two address signals which are applied sequentially to one pad when generating an internal address.

The present invention is also able to secure stability when generating an internal address.

### SUMMARY OF THE INVENTION

A preferred embodiment of the present invention of the internal address generation circuit includes a control unit outputting a internal command signal and at least more than two address strobe signals, wherein the outputted internal command signal and the outputted address strobe signals are different in terms of a strobe timing by decoding an external command signals; and an internal address generation unit inputting sequentially a first and a second address and outputting an internal address signal, wherein the internal address generation unit aligning the first and the second address signals in a row by using the internal command signal.

It is preferable that the internal address generation unit further includes an external address input unit outputting the first and the second address by buffering and latching at least more than two external addresses which are inputted sequentially to one pad.

Preferably, the external address input unit receives at least more than two addresses for at least more than two period of a clock signal, and includes an address buffer buffering the external address; and an address latch unit latching the buffered address signal in response to the clock signal.

The control unit includes a command decoder outputting the internal command signal and a first address strobe signal by decoding the external command signal in response to the clock; and a shift unit shifting the first address strobe signal, and outputting it as a second address strobe signal.

Preferably, the shift unit outputs the first address strobe signal as the second address strobe signal by delaying the first address strobe signal by one period.

The internal address generation unit includes a latch unit sequentially latching each address to latches which are arranged in a row in response to each address strobe signal, and aligning the addresses in a row; and an address generation unit outputting each address which is aligned in the latch unit as an internal address signal in response to the internal command signal

Here, each of the address strobe signals applied to each latch of the latch unit has a sequential delay difference corresponding to approximately one clock period. Further, the internal address generation unit outputs each address as an internal address signal in synchronization with the internal command signal. It is preferable that the internal address generation circuit includes more than two internal address generation unit having an address latch unit latching each address by using a corresponding address strobe signal; and an address generation unit outputting an address latched to the address latch unit as an internal address signal in response to the internal command signal

Preferably, the internal address generation unit is arranged such that it can correspond to each address which is inputted sequentially, and each address strobe signal applied to the internal address generation unit has a sequential delay difference corresponding to approximately one clock period.

The internal address generation unit includes a first internal address generation unit latching the first address in response to the first address strobe signal, and outputting it as a first internal address signal in response to the internal command signal; and a second internal address generation unit latching the second address in response to the second address strobe signal, and outputting it as a second internal address signal in response to the internal command signal.

At least one of the first and the second internal address generation unit includes an address latch unit latching the address in response to the first address strobe signal; and an address generation unit outputting the address latched to the address latch unit as the internal address signal in response to the internal command signal.

Preferably, the first address strobe signal and the second address strobe signal have a sequential delay difference corresponding to approximately one clock period.

The internal address generation unit includes a first internal address generation unit performing a first and second latching the first address in response to the first and the second address strobe signal, respectively and outputting the second latch signal as a first internal address signal in response to the internal command signal; and a second internal address generation unit latching the second address in response to the second address strobe signal, and outputting the latched signal as a second internal address signal in response to the internal command signal.

Here, the first internal address generation unit includes a first address latch unit latching the first address in response to the first address strobe signal; a second address latch unit performing a second latching for the first address latched to the first address latch unit as the internal address signal in response to the second address strobe signal; and an address generation unit outputting the first address latched to the second address latch unit as a first internal address signal in response to the internal command signal.

Further, the second internal address generation unit includes an address latch unit latching the second address in response to the second address strobe signal; and an address generation unit outputting the second address latched to the address latch unit as a second internal address signal in response to the internal command signal.

Preferably, the first and second the address strobe signal have a sequential delay difference corresponding to approximately one clock period.

One preferred embodiment of an internal address generation method of the present invention for generating the internal address by receiving a plurality of external address signals via the same pad includes the steps of: generating an internal command signal and a first address strobe signal by decoding an external command signal; and performing a first latching for an address signal in response to the first address strobe signal; generating a second address strobe signal by synchronizing the first address strobe signal with a clock, and shifting it; performing a first latching for the address signal in response to the second address strobe signal; and outputting the first and second latched address in response to the internal command signal.

Preferably, the first and second latched address are the different addresses which are applied sequentially from the same pad, and the first address strobe signal and the second address strobe signal have a sequential delay difference corresponding to approximately one clock period.

Further, at least more than one address of the first and second latched address performs a latching for matching to another address having a different latching timing.

### BRIEF DESCRIPTION OF THE DRAWINGS

FIG. 1 shows a block of a conventional internal address generation circuit in response to a first embodiment of the present invention.

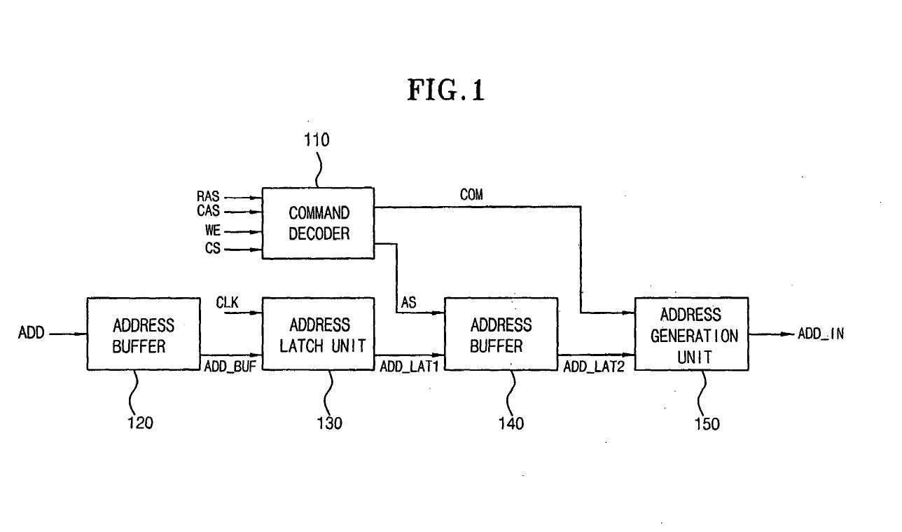

FIG. 2 shows an operation timing chart of FIG. 1

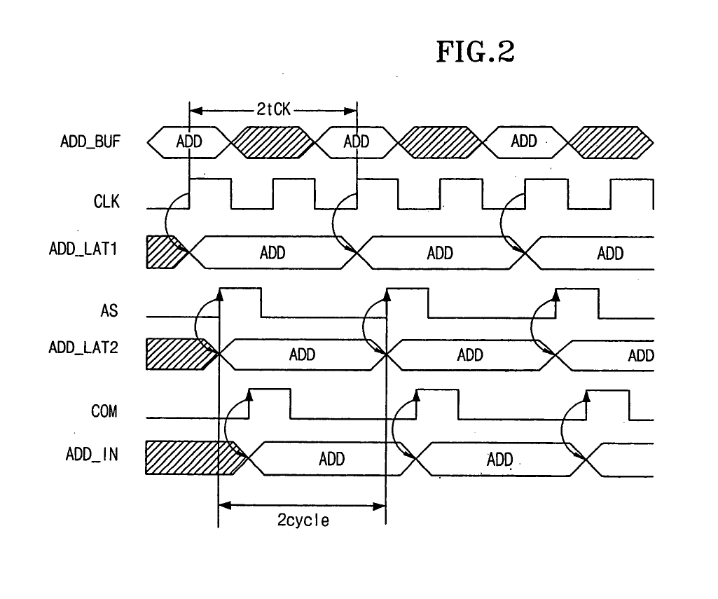

FIG. 3 shows a block of an internal address

FIG. 4 shows an operation timing chart of FIG. 3

FIG. 5 shows a block of an internal address generation circuit in response to a second embodiment of the present invention.

FIG. 6 shows an operation timing chart of FIG. 5.

### DETAILED DESCRIPTION OF SPECIFIC EMBODIMENTS

Below, the present will be explained in detail with referring to the drawings. The present invention has a structure in which a division-latching is performed for an external address which is inputted serially, aligned in a row, and the aligned address is synchronized with an internal command signal, and then is provided to an internal address.

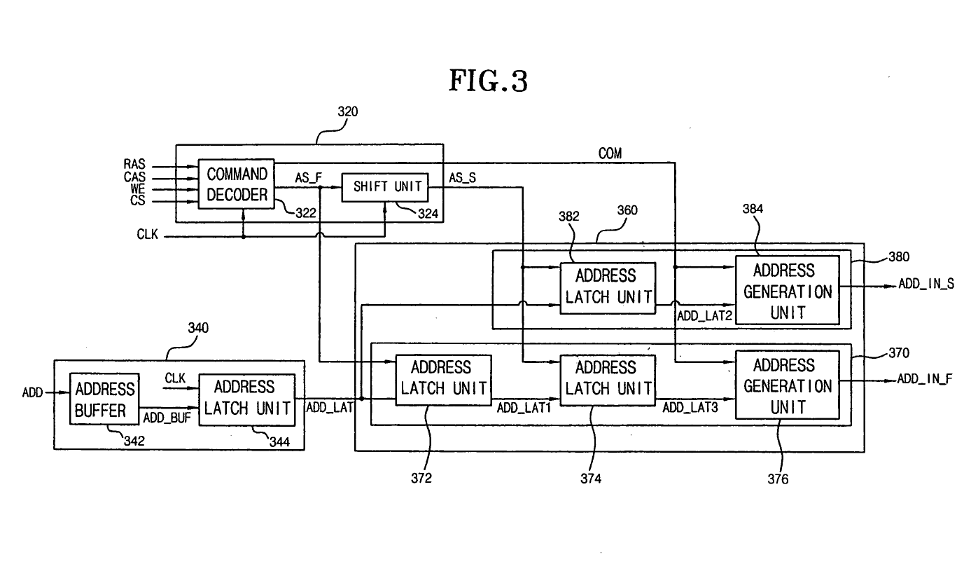

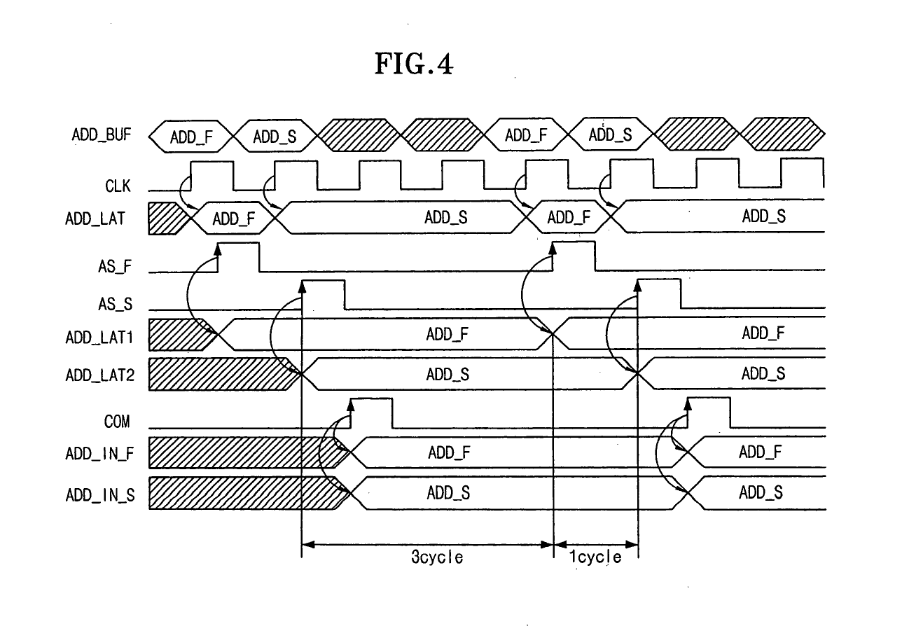

Referring to FIG. 3 and FIG. 4, an internal address generation circuit in response to a first embodiment of the present invention, and the operation waveforms will be explained. Here, tCCD is 4tCK. The internal address generation circuit includes a control unit 220, an external address input unit 240, and an internal address generation unit 260.

The control unit 220 includes a command decoder 222 and a shift unit 224, and decodes an external command signal, for example, RAS, CAS, WE, CS and outputs at least more than two address strobe signal AS_F, AS_S having a strobe timing which is different from that of an internal command signal COM and

The command decoder 222 decodes an external command signal such as RAS, CAS, WE, and CS by using a clock, and then outputs the internal command signal COM and the address strobe signal AS_F.

Here, the address strobe signal AS_F is a signal which is enabled in response to the command requiring an address such as reading, writing and pre-charging.

The shift unit 224 synchronizes the address strobe signal AS_F with each cycle of the clock CLK, and outputs the address strobe signal AS_S. That is, the shift unit 224 outputs the address strobe signal AS_S by delaying the address strobe signal AS_F by 1tCK.

The external address input unit 240 includes an address buffer 242 and an address latch unit 244, and an address ADD_LAT latched by buffering and latching the external address signal ADD into which at least more than two addresses are inputted sequentially to one pad.

The address buffer 242 amplifies a plurality of external address signals ADD(ADD_F, ADD_S) which are inputted sequentially to the same pad during at least 2tCK to the CMOS level, and outputs them as the buffered address signal ADD_BUF.

The address latch unit 244 latches the buffered address signal which is synchronized with a clock, and then outputs it as a latched address ADD_LAT. That is, in the address latch unit 244, the first address ADD_F which is synchronized with a first clock and is buffered is latched before it is applied to the second clock CLK, the second address ADD_S which is synchronized with a second clock and is buffered is latched during 3tCK.

The internal address generation unit 260 includes at least more than two internal address generation section 270, 280, aligns each address signal ADD_F, ADD_S included in the external address signal in a row by using at least more than two address strobe signals AS_F, AS_S, and outputs the addresses aligned based on the internal command signal COM as an internal address signal ADD_IN_F, ADD_IN_S.

The internal address generation unit 270 includes an address latch unit 270 and an address generation unit 274, and outputs the first address ADD_F included in the address signal ADD_LAT latched by the address strobe signal AS_F and the internal command signal COM as an internal address signal ADD_IN_F.

The address latch unit 272 latches the first address ADD_F included in the address signal ADD_LAT which is synchronized with the address strobe signal AS_F and is latched, and outputs it as the first address latch signal ADD_LAT1.

The address generation unit 274 synchronizes the first address latch signal ADD_LAT1 with the internal command signal COM and then outputs it as an internal address signal ADD_IN_F.

The internal address generation unit 280 includes an address latch unit 282 and an address generation unit 284, and outputs the second address ADD_F included in the address signal ADD_LAT latched by the address strobe signal AS_S and the internal command signal COM as an internal address signal ADD_IN_S.

The address latch unit 282 latches the second address ADD_S included in the address signal ADD_LAT which is synchronized with the address strobe signal AS_S and is latched, and then outputs it as the second address latch signal ADD_LAT2.

The address generation unit 284 synchronizes the second address latch signal ADD_LAT2 with the internal command signal COM and then outputs it as an internal address signal ADD_IN_S.

Referring to FIG. 4, since the address strobe signal AS_F and the address strobe signal AS_S are enabled by the phase difference of 1tCK, the first address latch signal ADD_LAT1 and the second address latch signal ADD_LAT2 are aligned such that the phase difference of 1tCK can be generated. Therefore, the interval during which the internal command signal COM is enabled, and the internal address signal ADD_IN_S and the internal address signal ADD_IN_F are stabilized becomes 3tCK(3cycle).

In this way, since a plurality addresses ADD_F, ADD_S which are applied sequentially to one pad are separated by the address strobe signal AS_F, AS_S, and then latched to the address latch unit 272, 282, a plurality of internal address signal ADD_IN_S, ADD_IN_F are generated.

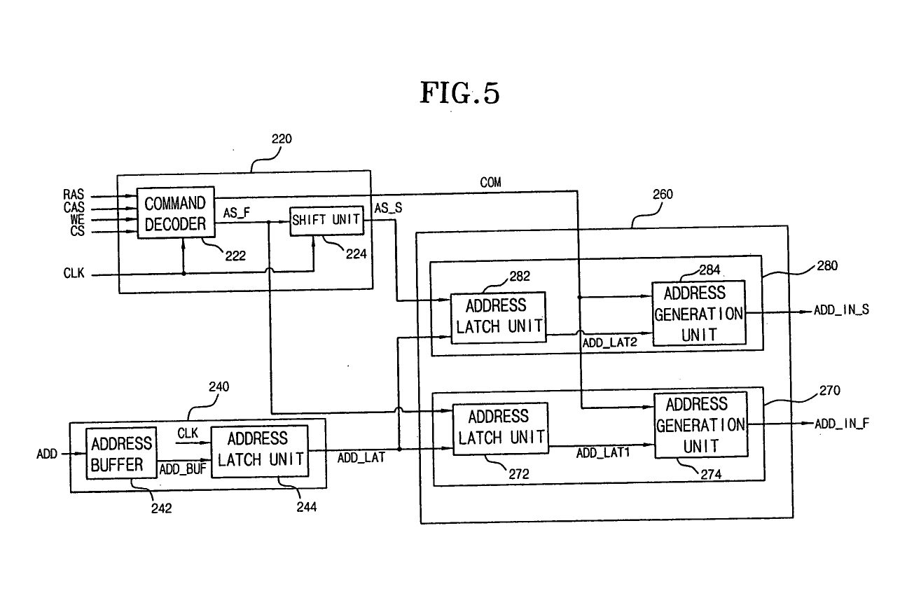

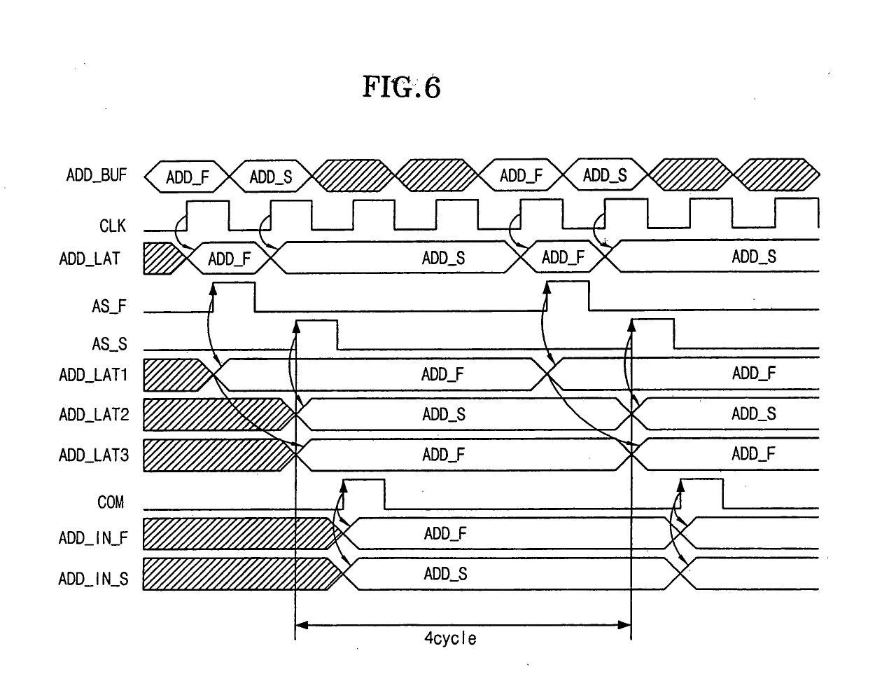

Referring to FIG. 5 and FIG. 6, an internal address generation circuit and the operation waveforms in response to a second embodiment of the present invention are explained. Here, tCCD is 4tCK.

The internal address generation circuit includes a control unit 320, an external address input unit 340, and an internal address generation unit 360, and these elements are formed such that they can correspond to a control unit 220, an external address input unit 240, and an internal address generation unit 260, respectively.

Only, an internal address generation unit 370 synchronizes the third address latch signal ADD_LAT3 latched by synchronizing the first address latch signal ADD_LAT1 with the address strobe signal AS_S with the internal command signal COM, and then outputs it as the first internal address signal ADD_IN_F.

In other words, the internal address generation unit 370 includes an address latch unit 372, an address latch unit 374, and an address generation unit 376.

The address latch unit 372 latches the first address ADD_F included in the address signal ADD_LAT which is synchronized with the address strobe signal AS_F and is latched, and then outputs it as the first address latch signal ADD_LAT1.

The address latch unit 374 synchronizes the first address latch signal ADD_LAT1 with the address strobe signal AS_S and latches, and then outputs it as the third address latch signal ADD_LAT3.

The address generation unit 376 synchronizes the third address latch signal ADD_LAT3 with the internal command signal COM, and then outputs it as the internal address signal ADD_IN_F.

That is the second address latch signal ADD_LAT2 and the third address latch signal ADD_LAT3 are aligned by the address strobe signal AS_S.

Referring to FIG. 6, since the first address latch signal ADD_LAT1 is synchronized with the address strobe signal AS_S and is latched, and thus the second address latch signal ADD_LAT2 applied to the address generation unit 376 and the third address latch signal ADD_LAT3 applied to the address generation unit 384 are aligned in a row, the stability interval of the internal address signal ADD_IN_F, ADD_IN_S which are synchronized with the internal command signal COM and is outputted is expanded into 4tCK, and stability of the internal address signal can be further improved.

The method generating an internal address is as follows.

First of all, the external address input unit 240 buffers a plurality of the external address signal ADD(for example, two external address signal ADD_F, and ADD_S during 2tCK) which are inputted sequentially to the same pad during a plurality of clocks.

Subsequently, the external address input unit 240 synchronizes the buffered address signal ADD_BUF with a clock and latches, and then outputs the latched address signal ADD_LAT.

Next, the internal address generation unit 260 synchronizes each address ADD_F, ADD_S of the latched address signal ADD_LAT with the address strobe signal AS_S, AS_F which are outputted from the control unit 220 and have the different strobe timings, and aligns them in a row by latching.

Further, the internal address generation unit 260 outputs the data ADD_LAT1, ADD_LAT2 which are synchronized with the internal command signal COM outputted from the control unit 220, and aligned as the internal address signal ADD_IN_F, ADD_IN_S.

The address strobe signal AS_S is generated by delaying the address strobe signal AS_F by 1tCK.

Further, the internal address generation unit 360 synchronizes the first address latch signal ADD_LAT3 latched by synchronizing the first address latch signal ADD_LAT1 with the address strobe signal AS_S with the internal command signal COM, and then outputs as the internal address signal ADD_IN_F. Therefore, the stabilized interval of the internal address signal ADD_IN_F, ADD_IN_S is expanded into 4tCK, and thus stability of the internal address signal can be further improved.

In this way, the internal address signal can be generated by separating a plurality of the external addresses in response to the address strobe signals having different strobe timings.

Therefore, in response to the present invention, there is an effect that an internal address can be generated by a plurality of address signals which are inputted sequentially to one pad.

Further, in response to the present invention, since the plurality of address signals is synchronized with an address strobe signal having a sequential delay, latched, aligned, and outputted, there is an effect that stability of the internal address can be enhanced.

Those skilled in the art will appreciate that the conceptions and specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

What is claimed is:

1. An internal address generation circuit comprising,
a control unit outputting a internal command signal and at least more than two address strobe signals, wherein the outputted internal command signal and the outputted address strobe signals are different in terms of a strobe timing by decoding external command signals; and
an internal address generation unit inputting sequentially a first and a second address and outputting an internal address signal, wherein the internal address generation unit latching the first and the second signal by using the address strobe signals and aligning the first and the second address signals in a row by using the internal command signal s.

2. The internal address generation circuit set forth in the claim 1, wherein the internal address generation unit further includes an external address input unit inputting external address signals from a pad, and the external address input unit outputting the first and the second address signals by buffering and latching the external address signals.

3. The internal address generation circuit set forth in the claim 2, wherein the external address input unit receiving at least more than two external addresses signals for at least more than two period of a clock signal.

4. The internal address generation circuit set forth in the claim 2, wherein the external address input unit includes an address buffer buffering the external address signals; and an address latch unit latching the buffered address signals in responseto a clock signal.

5. The internal address generation circuit set forth in the claim 1, wherein the control unit includes a command decoder inputting the external command signals, wherein the command decoder outputting the internal command signal and a first address strobe signal by decoding the external command signals in response to the clock; and a shift unit time shifting a first address strobe signal by delay outputting the first address strobe signal as a second address strobe signal.

6. The internal address generation circuit set forth in the claim 5, wherein the shift unit delay outputs the first address strobe signal as the second address strobe signal by delaying the first address strobe signal by approximately one clock period.

7. The internal address generation circuit set forth in the claim 1, wherein the internal address generation unit includes a latch unit sequentially latching each internal address signal arranged in a row in response to each address strobe signal, and aligning the internal address signals in a row; and an address generation unit inputing the internal command signal outputting each internal address signal which is aligned in the latch unit.

8. The internal address generation circuit set forth in the claim 7, wherein each of the address strobe signals applied to each latch of the latch unit exhibits a sequential delay difference corresponding to approximately one clock period.

9. The internal address generation circuit set forth in the claim 7, wherein the internal address generation unit outputs each external address signal as an internal address signal in synchronization with the internal command signal.

10. The internal address generation circuit set forth in the claim 1, wherein more than two internal address generation unit having an address latch unit latching each address signal by using a corresponding address strobe signal; and an address generation unit outputting an address signal latched to the address latch unit as an internal address signal in response to the internal command signal are included.

11. The internal address generation circuit set forth in the claim 10, wherein the internal address generation unit is arranged such that it can correspond to each address signal which is inputted sequentially.

12. The internal address generation circuit set forth in the claim 10, wherein each address strobe signal applied to the internal address generation unit has a sequential delay difference corresponding to approximately one clock period.

13. The internal address generation circuit set forth in the claim 1, wherein the internal address generation unit includes a first internal address generation unit latching the first address signalin response to the first address strobe signal, and outputting a first internal address signal in response to the internal command signal; and a second internal address generation unit latching the second address signal in response to the second address strobe signal, and outputting a second internal address signal in response to the internal command signal.

14. The internal address generation circuit set forth in the claim 13, wherein at least one of the first and the second internal address generation unit includes an address latch unit latching the address signal in response to the first address strobe signal; and an address generation unit outputting the address signal latched to the address latch unit as the internal address signal in response to the internal command signal.

15. The internal address generation circuit set forth in the claim 13, wherein the first address strobe signal and the second address strobe signal have a sequential delay difference corresponding to approximately one clock period.

16. The internal address generation circuit set forth in the claim 1, wherein the internal address generation unit includes a first internal address generation unit performing a first and second latching of the first address signal in response to the first and the second address strobe signal, respectively and outputting the second latch signal as a first internal address signal in response to the internal command signal; and a second internal address generation unit latching the second address signal in response to the second address strobe signal, and outputting the latched signal as a second internal address signal in response to the internal command signal.

17. The internal address generation circuit set forth in the claim 16, wherein the first internal address generation unit includes a first address latch unit latching the first address signal in response to the first address strobe signal; a second address latch unit performing a second latching for the first address signal latched to the first address latch unit as the internal address signal in response to the second address strobe signal; and an address generation unit outputting the first address signal latched to the second address latch unit as a first internal address signal in response to the internal command signal.

18. The internal address generation circuit set forth in the claim 16, wherein the second internal address generation unit includes an address latch unit latching the second address signal in response to the second address strobe signal; and an address generation unit outputting the second address signal latched to the address latch unit as a second internal address signal in response to the internal command signal.

19. The internal address generation circuit set forth in the claim 16, wherein the first and second the address strobe signal have a sequential delay difference corresponding to approximately one clock period.

20. An internal address generation method for generating the internal address signal by receiving a plurality of external address signals via a same pad, comprising the steps of:
generating an internal command signal and a first address strobe signal by decoding an external command signal; and
performing a first latching of an address signal in response to the first address strobe signal;
generating a second address strobe signal by synchronizing the first address strobe signal with a clock, and shifting the first address strobe signal;
performing a first latching for the address signal in response to the second address strobe signal; and
outputting the first and second latched address signals in response to the internal command signal.

21. The internal address generation method set forth in the claim 20, wherein the first and second latched address are applied sequentially from the same pad.

22. The internal address generation method set forth in the claim 20, wherein the first address strobe signal and the second address strobe signal have a sequential delay difference corresponding to approximately one clock period.

23. The internal address generation method set forth in the claim 20, wherein at least more than one address of the first and second latched address performs a latching for matching to another address having a different latching timing.
